(19) United States
(12) Patent Application Publication
(10) Pub. No.: US 2005/0158664 A1
(43) Pub. Date: Jul. 21, 2005

(54) Method of integrating post-etching cleaning process with deposition for semiconductor device

(76) Inventors: Joshua Tseng, Hsin-chu Hsien (TW); Ping Chuang, Taichung Hsien (TW); Hung-Jung Tu, Hualien (TW); Ching-Ya Wang, Taipei (TW); Yu-Liang Lin, Hsinchu Hsien (TW); Henry Lo, Hsinchu City (TW); Mei-Sheng Zhou, Singapore (SG)

Correspondence Address: THOMAS, KAYDEN, HOSTEMEYER & RISLEY LLP, 100 GALLERIA PARKWAY, SUITE 1750, ATLANTA, GA, 30339, US

(21) Appl. No.: 10/760,927

(22) Filed: Jan. 20, 2004

(51) Int. Cl. G03F 7/00; G03F 7/42

(52) U.S. Cl. 430/313; 430/314; 430/329

(57) ABSTRACT

A method of integrating a post-etching cleaning process with deposition for a semiconductor device. A substrate having a damascene structure formed by etching a dielectric layer formed thereon using an overlying photoresist mask as an etching mask is provided. A cleaning process is performed by a supercritical fluid to remove the photoresist mask and post-etching by-products. An interconnect layer is formed in-situ in the damascene structure using the supercritical fluid as a reaction medium, wherein the cleaning process and the subsequent interconnect layer formation are performed in one process chamber or in different process chambers of a processing tool.

### BACKGROUND

The present invention relates to a semiconductor process, and particularly to a method of integrating a post-etching cleaning process with deposition in a semiconductor wafer processing tool having one chamber or multiple chambers.

In the fabrication of integrated circuits or microelectronic devices, multilevel wiring structures are utilized to interconnect regions between one or more devices within the integrated circuits. The conventional method of forming such interconnect structures employs a damascene process.

The damascene process begins with deposition of a dielectric layer, such as a low dielectric constant (k) material layer, over a silicon wafer to serve as an intermetal dielectric (IMD) layer. Photolithography and etching are successively performed to form a trench or contact opening, or a dual damascene opening composed of such openings in the IMD layer. Finally, a metal layer, such as copper or aluminum, is deposited in the opening to complete the interconnect structure.

Conventionally, after etching is performed to form the opening in the IMD layer, the wafer undergoes a cleaning process in a cleaning chamber to remove the photoresist mask and the post-etching by-products, such as polymer or other chemical residue. Thereafter, the wafer is removed from the cleaning chamber to await deposition for subsequent metallization. During the waiting time, referred to as queue time (Q-time), the wafer is exposed to air, causing native or an undesired oxide formation on the surface of the silicon wafer layer formed on the lower metal layer of the wafer, impeding the subsequent processes. In order to remove such oxides, an additional cleaning process by plasma is performed prior to deposition, but results in damage to the surface of the low k dielectric layer. Moreover, the low k dielectric layer may interact with post-etching by-products and may absorb moisture while waiting for deposition, resulting in diminished dielectric properties.

Additionally, the removal of photoresist mask is usually performed by a gaseous plasma removal method. However, the low k dielectric layer is damaged by plasma, diminishing the dielectric properties. Moreover, the plasma removal method cannot completely remove the photoresist mask due to polymer formed on sidewalls of the photoresist mask, impeding subsequent processes.

U.S. Pat. No. 6,184,132 discloses an integrated cobalt silicide process for semiconductor devices, which employs an in-situ plasma cleaning process to remove native oxide formed on the silicon substrate prior to cobalt deposition. As mentioned above, however, plasma may damage the surface of the substrate during cleaning. Additionally, U.S. Pat. No. 6,395,642 discloses a method to improve copper integration, which is accomplished by integrating a copper seed layer formation process with the plasma cleaning process prior to copper electroplating. This method, while effective in removing copper oxide to increase the quality of the copper interconnects, still requires the mentioned queue time between the steps of removing photoresist mask and metal deposition.

It is therefore apparent that the art is in need of a novel process capable of solving problems caused by queue time that maintains the dielectric properties of the dielectric layer.

### SUMMARY

Accordingly, it is an object of the present invention to provide a method to eliminate air exposure of a substrate having a low dielectric constant (k) material layer thereon prior to metal deposition by integrating the post-etching cleaning process with deposition, thereby overcoming problems arising from queue time and increasing throughput.

It is another object of the present invention to provide a method to employ supercritical fluid technology, instead of the conventional plasma technology, for the post-etching cleaning process and the subsequent deposition, thereby effectively removing post-etching by-products and preventing damage of the low k material layer.

It is also an object of the present invention to provide a semiconductor device having an interconnect structure which is formed using supercritical fluid as a cleaning agent for cleaning and a reaction medium for deposition.

The above and other objects and advantages, which will be apparent to one of skill in the art, are achieved in the present invention which is directed to, in a first aspect, a method for forming an interconnect structure. First, a substrate covered by a dielectric layer having at least one opening defined by an overlying masking pattern layer is provided. Thereafter, a cleaning process is performed by a supercritical fluid to remove the masking pattern layer and etching by-products formed over the surfaces of the dielectric layer and the opening therein. Finally, the opening is in-situ filled with a conductive layer using the supercritical fluid as a reaction medium to complete the interconnect structure. In this aspect, the cleaning process is performed and the opening is in-situ filled in one process chamber of a processing tool or in different process chambers of a processing tool with multiple chambers.

The dielectric layer can be a low k material layer and the masking pattern layer can be a photoresist pattern layer.

Moreover, the supercritical fluid can be supercritical carbon dioxide (CO₂) and further includes a stripper chemical containing HF, NMP, CH₃COOH, MeOH, BLO, H₂SO₄, HNO₃, H₃PO₄, or TFAA dissolved therein.

Moreover, the conductive layer can be formed using an organometallic complex as a deposition precursor and using supercritical carbon dioxide as a reaction medium, wherein the organometallic complex includes Cu(hfac) (2-butyne), Cu(hfac)2, or Cu(dibm).

In another aspect of the invention, an integrated copper process is provided. First, a substrate covered by a dielectric layer having a damascene opening defined by an overlying masking pattern layer is provided. Next, a cleaning process is performed by a supercritical fluid to remove the masking pattern layer and etching by-products formed over the surfaces of the dielectric layer and the damascene opening therein. Finally, a copper layer is formed in-situ in the damascene opening using the supercritical fluid as a reaction medium. In the invention, the cleaning process is performed and the opening is in-situ filled in one process chamber of a processing tool or in different process chambers of a processing tool with multiple chambers.

The dielectric layer can be a low k material layer and the masking pattern layer can be a photoresist pattern layer.

Moreover, the supercritical fluid used in the cleaning process can be supercritical carbon dioxide (CO₂) and further includes a stripper chemical containing HF, NMP, CH₃COOH, MeOH, BLO, H₂SO₄, HNO₃, H₃PO₄, or TFAA dissolved therein.

Moreover, the copper layer can be formed using Cu(hfac)(2-butyne), Cu(hfac)2, or Cu(dibm) as a deposition precursor.

In yet another aspect of the invention, a semiconductor device is provided. The device includes a substrate, a low dielectric constant material layer, and an interconnect structure. The dielectric constant material layer is disposed overlying the substrate and has at least one damascene opening in an area pre-cleaned by a supercritical fluid. The interconnect structure is disposed in the damascene opening and is formed in-situ using the supercritical fluid as a reaction medium and using an organometallic complex as a deposition precursor after cleaning. The damascene opening is pre-cleaned and the interconnect structure is formed in one process chamber of a processing tool or in different chambers of a processing tool with multiple chambers.

Moreover, the supercritical fluid used in the cleaning can be supercritical carbon dioxide (CO₂) and further includes a stripper chemical containing HF, NMP, CH₃COOH, MeOH, BLO, H₂SO₄, HNO₃, H₃PO₄, or TFAA dissolved therein.

Moreover, the organometallic complex can be Cu(hfac) (2-butyne), Cu(hfac)2, or Cu(dibm) as a deposition precursor.

### BRIEF DESCRIPTION OF THE DRAWINGS

The present invention will become more fully understood from the detailed description given hereinbelow and the accompanying drawings, given by way of illustration only and thus not intended to be limitative of the present invention.

FIGS. 1a to 1d are cross-sections showing a method for forming an interconnect structure for damascene process according to the invention.

### DESCRIPTION

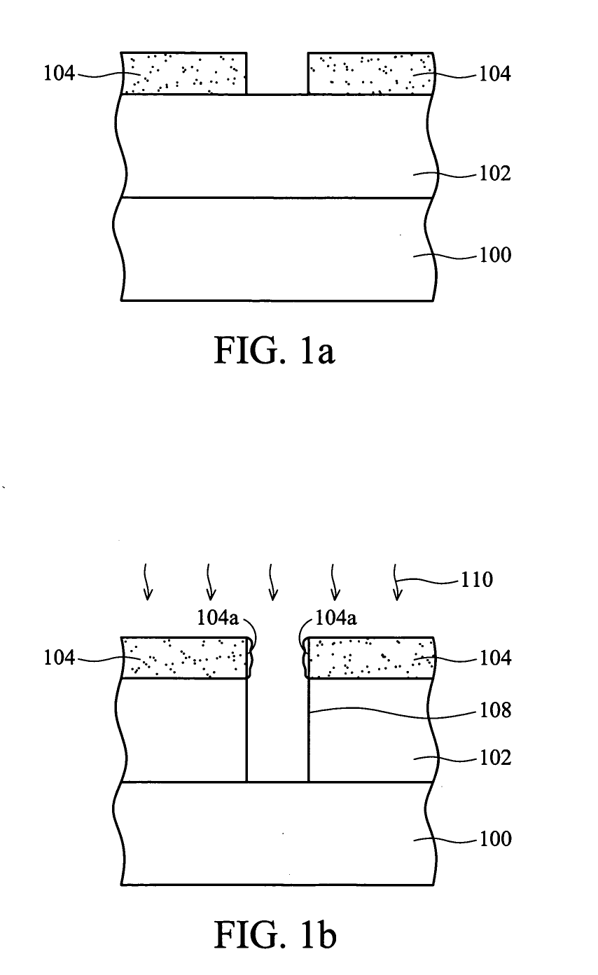

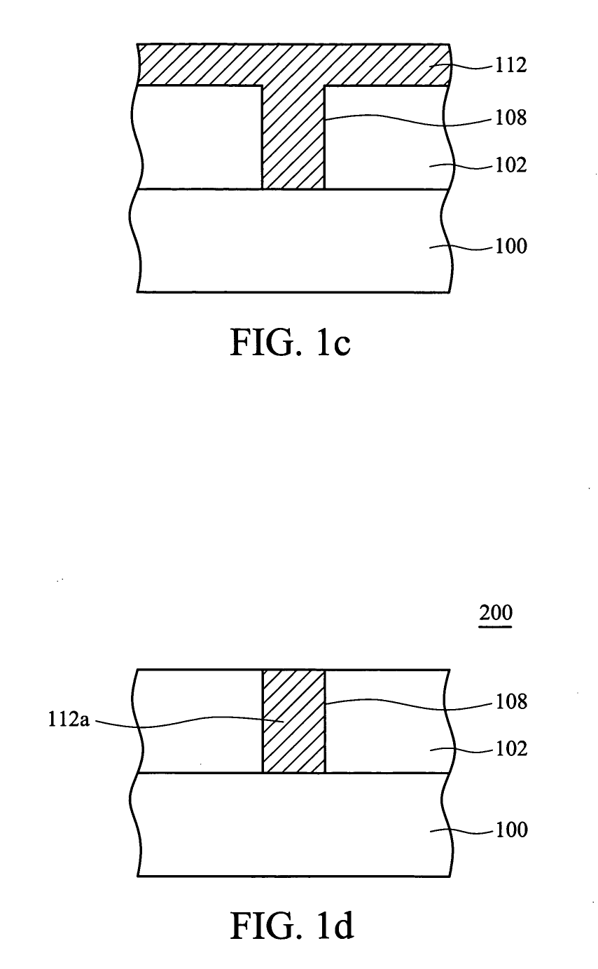

FIGS. 1a to 1d are cross-sections showing a method for forming an interconnect structure for damascene process according to the invention. First, in FIG. 1a, a substrate 100, such as a silicon substrate or other semiconductor substrate, is provided. The substrate 100 may contain a variety of elements, including, for example, transistors, resistors, and other semiconductor elements as are well known in the art. The substrate 100 may also contain other insulating layers or metal interconnect layers. In order to simplify the diagram, a flat substrate is depicted.

Next, a dielectric layer 102 is formed overlying the substrate 100. In the invention, the dielectric layer 102 is used as an interlayer dielectric (ILD) layer or an intermetal dielectric (IMD) layer. For example, the dielectric layer 102 may be silicon dioxide, PSG, BPSG, or low dielectric constant (k) material, such as FSG. Moreover, the dielectric layer 102 can be formed by conventional deposition, such as plasma enhanced chemical vapor deposition (PECVD), low pressure CVD (LPCVD), atmospheric pressure CVD (APCVD), high-density plasma CVD (HDPCVD) or other suitable CVD. Additionally, an etching stop layer (not shown), such as a silicon nitride layer, can be optionally deposited on the substrate 100 by LPCVD using SiCl₂H₂ and NH₃ as reaction sources prior to deposition of dielectric layer 102. Moreover, an anti-reflective layer (not shown) can be optionally deposited overlying the dielectric layer 102. The anti-reflective layer may be SiON formed by CVD using, for example, SiH₄, O₂, and N₂ as process gases.

Thereafter, a masking layer (not shown), such as photoresist, is coated on the dielectric layer 102, and photolithography is subsequently performed on the masking layer to form a masking pattern layer 104 having at least one opening 106 to expose a portion of dielectric layer 102 for damascene structure definition.

Next, in FIG. 1b, conventional etching, such as reactive ion etching (RIE), is performed on the dielectric layer 102 using the masking pattern layer 104 as an etching mask to form a damascene opening 108 therein. The damascene opening 108 can be a trench, contact or other opening.

Next, a series of critical steps of the invention are performed. A cleaning process 110 is first performed by a supercritical fluid, such as supercritical carbon dioxide (CO₂) to remove the masking pattern layer 104 and the post-etching by-products formed on the surfaces of the dielectric layer 102 and damascene opening 108 therein. That is, the cleaning process 110 of the invention includes stripping and conventional cleaning.

A gas in the supercritical state is referred to as a supercritical fluid. That is, a gas enters the supercritical state when the combination of pressure and temperature of the environment is above a critical state. For example, the critical temperature of CO₂ is about 31° C., and the critical pressure of CO₂ is about 72.6. atm. In the invention, the cleaning process conditions range from 31˜400° C. and from 72˜400 atm. Typically, the diffusivity and viscosity of the supercritical fluid is similar to a gas phase while the density is substantially equal to a liquid phase. Accordingly, the supercritical fluid may have a stripping chemical dissolved therein. The supercritical fluid is utilized in stripping and cleaning, to remove the masking pattern layer 104 and post-etching by-products, such as polymer 104a formed on the sidewall of the masking pattern layer 104 or other chemical residue (not shown) formed on the surfaces of the dielectric layer 102 and the damascene opening 108 therein. In the invention, the stripper chemical comprises hydrofluoric acid (HF), N-methyl-2-pyrrolidone (NMP), CH₃COOH, MeOH, butyrolactone (BLO), H₂SO₄, HNO₃, H₃PO₄, or trifluoroacetic acid (TFAA).

Next, in FIG. 1c, a conductive layer 112, such as copper, aluminum, or other well known interconnect material, is formed in-situ overlying the dielectric layer 102 and fills the damascene opening 108. In the invention, in order to prevent oxide or any chemical residue from forming or undesired chemical reactions from occurring with the dielectric layer 102 when the cleaned substrate 100 is exposed to air, the conductive layer 112 is formed in-situ by a supercritical fluid method and can be easily integrated with the previous cleaning process. For example, after the cleaning process is performed on the substrate 100 in a vacuum chamber, deposition is subsequently performed using an organometallic complex as a deposition precursor and using a supercritical CO₂ as a deposition medium without breaking the vacuum. That is, the cleaning process and the deposition can be successively performed in one chamber of a processing tool or in different chambers of a processing tool with multiple chambers. In the invention, for example, the organometallic complex comprises Cu(hfac)(2-butyne) (copper(II) hexafluoroacethyl acetonate-2-butyne), Cu(hfac)2, or Cu(dibm) (copper diisobutyrylmethanato) for copper interconnect fabrication. Additionally, a diffusion barrier layer (not shown), such as titanium nitride, tantalum nitride, tungsten nitride, or the like, is typically formed on the surfaces of the dielectric layer 102 and the damascene opening 108 prior to conductive layer 112 deposition. Additionally, the diffusion barrier layer can be formed in-situ by such supercritical fluid method using another suitable organometallic complex as a deposition precursor.

Finally, in FIG. 1d, the excess conductor layer 112 over the dielectric layer 102 is removed by an etching back process or polishing, such as chemical mechanical polishing (CMP), to leave a portion of conductive layer 112a in the damascene opening 108 to serve as an interconnect and complete the interconnect structure fabrication.

A cross-section of a semiconductor device 200 according to the invention is shown in FIG. 1d. The semiconductor device 200 includes a substrate 100, a dielectric layer 102, and an interconnect structure 112a. The dielectric layer 102, such as a low dielectric constant layer, is disposed overlying the substrate 100, and has at least one damascene opening 108 in an area pre-cleaned by a supercritical fluid, such as supercritical CO₂, having HF, NMP, CH₃COOH, MeOH, BLO, H₂SO₄, HNO₃, H₃PO₄, or TFAA dissolved therein to serve as a stripper. Here, the damascene opening 108 can be a trench or contact opening. The interconnect structure 112a is disposed in the damascene opening 108, which is formed in-situ using the supercritical fluid as a reaction medium and using an organometallic complex, such as Cu(hfac)(2-butyne), Cu(hfac)2, or Cu(dibm), as a deposition precursor after cleaning. Moreover, the cleaning and the interconnect structure 112a fabrication can be performed in one process chamber of a processing tool or in different processing chambers of a processing tool with multiple chambers.

According to the invention, the cleaning process and the subsequent deposition for metallization are successively performed without breaking the vacuum between steps. That is, air exposure of the cleaned substrate can be eliminated, thereby preventing oxide or chemical residue formation and undesirable reactions or moisture absorption from occurring. Accordingly, the semiconductor device reliability and throughput are increased by eliminating the queue time issue. Moreover, compared to the related art, since the post-etching cleaning process is performed by supercritical fluid technology, the post-etching by-products can be effectively removed without damaging the low k material layer, thereby increasing device quality. Moreover, the post-etching cleaning process can be easily integrated with deposition using supercritical fluid as a cleaning agent for cleaning and a reaction medium for deposition, thereby simplifying the process, reducing processing tool space and reduce the fabrication costs.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art) . Therefore, the scope of the appended claims should be accorded the broadest interpretation so as to encompass all such modifications and similar arrangements.

1. A method for forming an interconnect structure, comprising the steps of:
providing a substrate covered by a dielectric layer having at least one opening defined by an overlying masking pattern layer;
performing a cleaning process by a supercritical fluid to remove the masking pattern layer and etching by-products formed over the surfaces of the dielectric layer and the opening therein; and
in-situ filling the opening with a conductive layer to complete the interconnect structure.

2. The method of claim 1, wherein the dielectric layer is a low dielectric constant material layer.

3. The method of claim 1, wherein the opening a trench, or contact opening.

4. The method of claim 1, wherein the masking pattern layer is a photoresist pattern layer.

5. The method of claim 1, wherein the supercritical fluid is supercritical carbon dioxide.

6. The method of claim 1, wherein the supercritical fluid further comprises a stripper chemical containing HF, NMP, CH₃COOH, MeOH, BLO, H₂SO₄, HNO₃, H₃PO₄, or TFAA dissolved therein.

7. The method of claim 1, wherein the conductive layer is formed using an organometallic complex as a deposition precursor and using supercritical carbon dioxide as a reaction medium.

8. The method of claim 7, wherein the organometallic complex comprises Cu(hfac)(2-butyne), Cu(hfac)2, or Cu(dibm).

9. The method of claim 1, wherein the steps of performing the cleaning process and in-situ filling the opening are in one process chamber of a processing tool.

10. The method of claim 1, wherein the steps of performing the cleaning process and in-situ filling the opening are in different process chambers of a processing tool with multiple chambers.

11. An integrated copper process, comprising the steps of:
providing a substrate covered by a dielectric layer having a damascene opening defined by an overlying masking pattern layer;
performing a cleaning process by a supercritical fluid to remove the masking pattern layer and etching by-products formed over the surfaces of the dielectric layer and the damascene opening therein; and
in-situ forming a copper layer in the damascene opening using the supercritical fluid as a reaction medium.

12. The method of claim 11, wherein the dielectric layer is a low dielectric constant material layer.

13. The method of claim 11, wherein the damascene opening comprises a trench or contact opening.

14. The method of claim 11, wherein the masking pattern layer is a photoresist pattern layer.

15. The method of claim 11, wherein the supercritical fluid is supercritical carbon dioxide.

16. The method of claim 11, wherein the supercritical fluid used in the cleaning process further comprises a stripper chemical of HF, NMP, CH₃COOH, MeOH, BLO, H₂SO₄, HNO₃, H₃PO₄, or TFAA dissolved therein.

17. The method of claim 11, wherein the copper layer is formed using Cu(hfac)(2-butyne), Cu(hfac)2, or Cu(dibm) as a deposition precursor.

18. The method of claim 11, wherein the steps of the cleaning process and in-situ formation of the copper layer are performed in one process chamber of a processing tool.

19. The method of claim 11, wherein the steps of the cleaning process and in-situ filling of the opening are performed in different process chambers of a processing tool with multiple chambers.

20. A semiconductor device, comprising:
a substrate;
a low dielectric constant material layer disposed overlying the substrate and having at least one damascene opening in an area cleaned by a supercritical fluid; and
an interconnect structure disposed in the damascene opening and formed in-situ using the supercritical fluid as a reaction medium and using an organometallic complex as a deposition precursor after cleaning.

21. The semiconductor device of claim 20, wherein the damascene opening comprises a trench or contact opening.

22. The semiconductor device of claim 20, wherein the supercritical fluid is supercritical carbon dioxide.

23. The semiconductor device of claim 20, wherein the supercritical fluid used in the cleaning further comprises a stripper chemical of HF, NMP, CH₃COOH, MeOH, BLO, H₂SO₄, HNO₃, H₃PO₄, or TFAA dissolved therein.

24. The semiconductor device of claim 20, wherein the organometallic complex comprises Cu(hfac)(2-butyne), Cu(hfac)2, or Cu(dibm).

25. The semiconductor device of claim 20, wherein the damascene opening is pre-cleaned and the interconnect structure is formed in-situ in one process chamber of a processing tool.

26. The semiconductor device of claim 20, wherein the damascene opening is pre-cleaned and the interconnect structure is formed in-situ in different process chambers of a processing tool with multiple chambers.
